(19) United States
(12) Patent Application Publication
(10) Pub. No.: US 2022/0005505 A1
(43) Pub. Date: Jan. 6, 2022

(54) Sputtering Target, Method for Producing Laminated Film, Laminated Film and Magnetic Recording Medium

(71) Applicant: JX Nippon Mining & Metals Corporation, Tokyo (JP)

(72) Inventors: Masayoshi Shimizu, Ibaraki (JP); Yasuyuki Iwabuchi, Ibaraki (JP); Manami Masuda, Ibaraki (JP)

(21) Appl. No.: 17/475,481

(22) Filed: Sep. 15, 2021

Related U.S. Application Data
(62) Division of application No. 16/344,372, filed on Apr. 24, 2019.

(30) Foreign Application Priority Data
Sep. 21, 2017 (JP) 2017-180830

(51) Int. Cl. G11B 5/73; C23C 14/16; C23C 14/34; G11B 5/851; H01F 41/18; H01J 37/34

(52) U.S. Cl. CPC G11B 5/73917; C23C 14/165; C23C 14/3407; H01J 2237/332; H01F 41/183; H01J 37/3426; G11B 5/851

(57) ABSTRACT

A sputtering target according to the present invention contains Co and one or more metals selected from the group consisting of Cr and Ru, as metal components, wherein a molar ratio of the content of the one or more metals to the content of Co is ½ or more, and wherein the sputtering target contains Nb₂O₅ as a metal oxide component.

### CROSS-REFERENCE TO RELATED APPLICATIONS

This application is a divisional of U.S. application Ser. No. 16/344,372 filed Apr. 24, 2019, which is the U.S. national stage of PCT/JP2018/030436 filed Aug. 16, 2018, which claims the priority benefit of JP application No. 2017-180830, filed on Sep. 21, 2017, the respective disclosures of each of which are hereby incorporated by reference in their entirety for all purposes herein.

### TECHNICAL FIELD

The present invention relates to a sputtering target which contains Co and Cr and/or Ru as metal components and is suitable for use in forming an intermediate layer or the like between a base layer and a magnetic layer of a perpendicular magnetic recording medium, for example; to a method for producing a laminated film; and to a magnetic recording medium. More particularly, the present invention proposes a technique capable of contributing to production of a hard disk drive having high density.

### BACKGROUND ART

In a hard disk drive, a perpendicular magnetic recording system for recording magnetism in a direction perpendicular to a recording surface has been put to practical use. This method is widely adopted because it enables high-density recording as compared with an in-plane magnetic recording method.

The magnetic recording medium in the perpendicular magnetic recording method generally has a structure in which a base layer such as an adhesion layer, a soft magnetic layer, a seed layer and a Ru layer, an intermediate layer, a magnetic layer, and a protective layer, and the like are sequentially laminated on a substrate such as aluminum or glass. Among them, in a lower part of the magnetic layer is a granular film in which SiO₂ or other metal oxide is dispersed in a Co—Pt based alloy containing Co as a main component, and the granular layer has high saturation magnetization Ms and magnetic anisotropy Ku. Further, the intermediate layer laminated on a lower side of the magnetic layer includes a structure having a Co—Cr—Ru based alloy or the like dispersing the similar metal oxide therein. The intermediate layer may contain a relatively large amount of Ru, Cr or the like in order to render the intermediate layer nonmagnetic.

In such a magnetic layer and an intermediate layer, the above metal oxide that will be a nonmagnetic material is precipitated at grain boundaries of magnetic particles such as a Co alloy or the like oriented in the vertical direction to reduce magnetic interaction, thereby improving noise characteristics and achieving high recording density.

In general, each layer such as the magnetic layer and the intermediate layer is formed by sputtering a material onto a substrate using a sputtering target having a predetermined composition or structure to form a film. Conventionally, such a type of technology is disclosed in Patent Document 1 and the like.

### CITATION LIST

### Patent Literature

Patent Document 1: Japanese Patent No. 5960287 B

### SUMMARY OF INVENTION

### Technical Problem

To realize high density of the hard disk drive, there are needs for an increase in the magnetic anisotropy Ku for ensuring thermal stability and high magnetic separation of the magnetic particles for high resolution.

However, the magnetic layer having high saturation magnetization Ms as described above has a strong exchange coupling between the magnetic particles, so that the magnetic layer has poor magnetic separation of the magnetic particles. Here, if a large amount of a metal oxide is added in order to improve the magnetic separation, the metal oxide will enter the magnetic particles to deteriorate crystallinity of the magnetic particles, whereby the saturation magnetization Ms and the magnetic anisotropy Ku are decreased accordingly.

An object of this invention is to solve such problems of the prior art. An object of this invention is to provide a sputtering target, a method for producing a laminated film, a laminated film and a magnetic recording medium, which can improve magnetic separation between the magnetic particles, without significantly lowering magnetic anisotropy of a magnetic layer in a magnetic recording medium.

### Solution to Problem

As a result of intensive studies, the inventors have found that when Nb₂O₅ is used as a metal oxide for a nonmagnetic material to be dispersed in a Co alloy which is a magnetic material for a magnetic layer and an intermediate layer, in addition to or in place of SiO₂ conventionally used, the magnetic separation between the magnetic particles can be significantly improved even if the content of the metal oxide is not increased so much. Further, the present inventors have found that this can allow high saturation magnetization Ms and high magnetic anisotropy Ku of the magnetic layer mainly based on Co—Pt to be maintained. It is believed that this is because Nb₂O₅ has reasonable wettability to Co and can be present as a stable oxide even if a part of oxygen is lacked, although the present invention is limited to such a theory.

Based on such findings, a sputtering target according to the present invention contains Co and one or more metals selected from the group consisting of Cr and Ru, as metal components, wherein a molar ratio of the content of the one or more metals selected from the group consisting of Cr and Ru to the content of Co is ½ or more, and wherein the sputtering target contains Nb₂O₅ as a metal oxide component.

It is preferable that the sputtering target according to the present invention contains only Nb₂O₅ as a metal oxide component, and the sputtering target has a content of Nb₂O₅ of from 5 mol % to 15 mol %.

Alternatively, it is preferable that the sputtering target according to the present invention has a content of Nb₂O₅ of from 2 mol % to 5 mol % and further comprises at least one metal oxide other than Nb₂O₅, and wherein the sputtering target has a total content of metal oxides including Nb₂O₅ of 30 vol % or more.

In this case, it is preferable that the at least one metal oxide other than the Nb₂O₅ is at least one metal oxide selected from the group consisting of TiO₂, SiO₂, B₂O₃, CoO, Co₃O₄, Cr₂O₃, Ta₂O₅, ZnO and MnO.

Preferably, the sputtering target according to the present invention contains Co in an amount of from 15 mol % to 60 mol %.

Preferably, the sputtering target according to the present invention contains Cr and/or Ru, and wherein a total content of Cr and Ru is from 30 mol % to 60 mol %.

The sputtering target according to the present invention may further contain Pt in an amount of from 5 mol % to 30 mol % as a metal component.

A method for producing a laminated film according to the present invention comprises forming an intermediate layer on a base layer containing Ru by sputtering using any one of the sputtering targets described above.

Preferably, the method for producing the laminated film according to the present invention further comprises forming a magnetic layer on the intermediate layer by sputtering using a sputtering target containing Co and Pt as metal components.

A laminated film according to the present invention comprises: a base layer containing Ru; and an intermediate layer formed on the base layer, the intermediate layer containing Co and one or more metals selected from the group consisting of Cr and Ru as metal components, the intermediate layer having a molar ratio of the content of the one or more metals selected from the group consisting of Ru and Co to the content of Co of ½ or more; and a magnetic layer formed on the intermediate layer, the magnetic layer containing Co and Pt as metal components, wherein the intermediate layer contains Nb₂O₅ as a metal oxide component.

A magnetic recording medium according to the present invention comprises the laminated film as described above.

### Advantageous Effects of Invention

According to the present invention, Nb₂O₅ is contained as a metal oxide component, so that it is possible to achieve both good magnetic separation between magnetic particles and high magnetic anisotropy Ku.

### BRIEF DESCRIPTION OF DRAWINGS

The patent or application file contains at least one drawing executed in color. Copies of this patent or patent application publication with color drawings will be provided by the Office upon request and payment of the necessary fee.

FIG. 1 is a schematic view showing a layer structure of a laminated film produced in Examples.

### DESCRIPTION OF THE PREFERRED EMBODIMENTS

Embodiments of the present invention will be described in detail below.

In an embodiment, a sputtering target according to the present invention contains Co and one or more metals selected from the group consisting of Cr and Ru, as metal components, and has a molar ratio of the content of the one or more metals selected from the group consisting of Cr and Ru to the content of Co of ½ or more, and contains Nb₂O₅ as a metal oxide component.

More particularly, the sputtering target has a structure in which a metal oxide containing Nb₂O₅ is dispersed in an alloy made of Co and one or more metals selected from the group consisting of Ru and Cr.

The sputtering target is particularly preferably used for forming an intermediate layer located between a base layer and a magnetic layer in a perpendicular magnetic recording type magnetic recording medium. In this case, in the intermediate layer formed by sputtering using the sputtering target, the above metal components form a base of magnetic particles in the magnetic layer and the metal oxide containing Nb₂O₅ forms a base of the nonmagnetic grain boundary material containing the metal oxide in the magnetic layer, thereby improving orientation of the magnetic grains oriented in the vertical direction and also uniformly distributing the grain boundary material around the periphery, so that the magnetic interaction between the magnetic grains is effectively reduced.

### (Composition)

The metal component of the sputtering target is mainly composed of Co, and, in addition, contains at least one of Cr and Ru. In particular, the metal component is a Co alloy containing Cr and/or Ru.

The content of Co is preferably from 15 mol % to 60 mol %. If the content of Co is too high, there is a concern that the sputtering target becomes ferromagnetic. On the other hand, if the Co content is too low, the hcp structure may not be stabilized or the lattice constant of the upper magnetic layer may significantly change. From this viewpoint, the Co content is more preferably from 30 mol % to 60 mol %.

When Cr and/or Ru is/are contained as a metal component(s), the total content of Cr and Ru is preferably from 30 mol % to 60 mol %. If the total content of Cr and Ru is too high, the hcp structure may not be stabilized or the lattice constant of the upper magnetic layer may significantly change. On the other hand, if the total content of Cr and Ru is too low, there is a concern that the sputtering target becomes ferromagnetic.

It is preferable that one or more metals selected from the group consisting of Cr and Ru is contained in an amount such that the molar ratio to the Co content is ½ or more. This is because if the molar ratio of the content of the one or more metals selected from the group consisting of Cr and Ru to the content of Co is less than ½, there is a concern that the sputtering target becomes ferromagnetic. From this viewpoint, the molar ratio of the content of one or more metals selected from the group consisting of Cr and Ru to the content of Co is still more preferably ⅔ or more. On the other hand, if the molar ratio is too high, the hcp structure may not be stabilized or the lattice constant of the upper magnetic layer may significantly change. Therefore, the molar ratio may preferably be 3 or less, and more preferably 1 or less.

The sputtering target according to the embodiment of the present invention may further contain Pt in an amount of from 5 mol % to 30 mol % as a metal component. The containing of Pt provides an advantage that the lattice constant can be matched to the magnetic layer to improve crystallinity of the magnetic layer and the magnetic anisotropy near the interface with the intermediate layer that is the magnetic layer can be improved. More preferably, the total content of Pt is from 15 mol % to 25 mol %. Many of these metal elements are usually contained as metal components, but some of them may be included as metal oxides by being oxidized by sintering in the production, which will be described below.

The sputtering target according to the present invention contains at least Nb₂O₅ as a metal oxide component. Nb₂O₅ has improved separability from Co alloy particles as compared with TiO₂, SiO₂ or the like which is the main metal oxide in the conventional sputtering target, has better wettability, has a wider grain boundary width composed of the metal oxide and can decrease dispersion of the width. Therefore, by containing Nb₂O₅, the separation between particles can be increased without decreasing a particle diameter of the magnetic layer, and both higher magnetic anisotropy and a decrease in a magnetic cluster size can be achieved.

The content of Nb₂O₅ is preferably from 5 mol % to 15 mol %. If the content of Nb₂O₅ is lower, there is a possibility that the above effect cannot be sufficiently obtained. On the other hand, if the content of Nb₂O₅ is higher, the metal particles will become small so that the crystallinity of the upper magnetic layer may be deteriorated.

On the other hand, the sputtering target according to the embodiment of the present invention may contain, in addition to Nb₂O₅, metal oxides such as TiO₂, SiO₂, B₂O₃, CoO, Co₃O₄, Cr₂O₃, Ta₂O₅, ZnO and MnO as metal oxide components. In particular, when such metal oxides are contained, a satisfactory effect can be obtained even if the content of Nb₂O₅ is from 2 mol % to 5 mol %.

When containing the above metal oxides other than Nb₂O₅, the total content of all the metal oxides including Nb₂O₅ is preferably 30 vol % or more. If the total content of the metal oxides is less than 30 vol %, the separation of the magnetic particles in the upper magnetic layer may become insufficient. For this reason, it is more preferable that the total content of metal oxides is 35 vol % or more.

On the other hand, if the total content of the metal oxides is too high, it is considered that the metal particles become small and the crystallinity of the upper magnetic layer is deteriorated. Therefore, the total content of the metal oxides is preferably 60 vol % or less.

### (Method for Producing Sputtering Target)

The above sputtering target can be produced by a powder sintering method, and specific examples thereof are as follows.

First, as metal powder, Co powder, Cr powder and/or Ru powder, and optionally further Pt powder, are prepared. The metal powder may be powder of not only a single element but also an alloy. The particle diameter of the metal power is preferably in a range of from 1 μm to 10 μm, in terms of enabling homogeneous mixing to prevent segregation and coarse crystallization. When the particle size of the metal powder is more than 10 μm, oxide particles as described below may not be uniformly dispersed, and when it is less than 1 μm, the sputtering target may deviate from the desired composition due to the oxidation of the metal powder.

Further, as the oxide powder, at least Nb₂O₅ powder and optionally at least one powder selected from the group consisting of SiO₂ powder, TiO₂ powder, B₂O₃ powder, CoO powder, Co₃O₄ powder, Cr₂O₃ powder, Ta₂O₅ powder, ZnO powder and MnO powder are prepared. The oxide powder has a particle diameter in a range of from 1 μm to 30 μm. This can lead to more uniform dispersion of the oxide particles in the metal phase when the oxide powder is mixed with the metal powder, and fired under pressure. If the particle diameter of the oxide powder is more than 30 μm, coarse oxide particles may be formed after firing under pressure. On the other hand, if it is less than 1 μm, agglomeration of the oxide powders may occur.

The above metal powder and oxide powder are weighed so as to provide a desired composition, and mixed and pulverized using a known way such as a ball mill. In this case, it is desirable to fill the inside of a container used for the mixing/pulverizing with an inert gas to suppress the oxidation of the raw material powder as much as possible. This can provide mixed powder in which predetermined metal powder and oxide powder are uniformly mixed.

The mixed powder thus obtained is then sintered under pressure in a vacuum atmosphere or an inert gas atmosphere, and formed into a predetermined shape such as a disk shape. Herein, various pressure sintering methods can be employed such as a hot press sintering method, a hot hydrostatic sintering method, a plasma discharge sintering method and the like. Among them, the hot hydrostatic sintering method is effective in terms of improvement of density of a sintered body.

A retention temperature during the sintering is in a temperature range of from 700 to 1500° C., and particularly preferably from 800° C. to 1400° C. A time for maintaining the temperature in this range is preferably 1 hour or more.

A pressing pressure during the sintering is preferably from 10 MPa to 40 MPa, and more preferably from 25 MPa to 35 MPa.

This can allow the oxide particles to be more uniformly dispersed in the metal phase.

The sintered body obtained by the pressure sintering can be subjected to cutting into a desired shape using a lathe or the like or other mechanical processing to produce a sputtering target.

### (Laminated Film)

The laminated film includes, at least, a base layer; an intermediate layer formed on the base layer; and a magnetic layer formed on the intermediate layer.

More particularly, the base layer contains Ru, and generally, it is composed of Ru, or it is a layer mainly based on Ru.

The intermediate layer contains, as metal components, Co and one or more metals selected from the group consisting of Cr and Ru, has a molar ratio of the content of one or more metals selected from the group consisting of Cr and Ru to the content of Co of ½ or more, and contains Nb₂O₅ as a metal oxide component.

The intermediate layer can be formed by the sputtering using the sputtering target as described above.

Therefore, as with the sputtering target described above, the content of Nb₂O₅ in the intermediate layer may be from 5 mol % to 15 mol %, or when the intermediate layer contains other metal oxides, the content of Nb₂O₅ may be from 2 mol % to 5 mol %. The intermediate layer may further contain metal oxides other than Nb₂O₅ and may have a total content of metal oxides including Nb₂O₅ of 30 vol % or more. Here, the metal oxides other than Nb₂O₅ may be at least one selected from TiO₂, SiO₂, B₂O₃, CoO, Co₃O₄, Cr₂O₃, Ta₂O₅, ZnO and MnO.

The Co content of the intermediate layer may be from 15 mol % to 60 mol %, and the total content of Cr and Ru may be from 30 mol % to 60 mol %. Further, the intermediate layer may contain Pt in an amount of from 5 mol % to 30 mol % as a metal component.

The magnetic layer contains Co and Pt as metal components, and may contain a metal oxide(s) selected from metal oxides such as Nb₂O₅, TiO₂, SiO₂, B₂O₃, CoO, Co₃O₄, Cr₂O₃, Ta₂O₅, ZnO and MnO. It is preferable that Nb₂O₅ is contained in the metal oxide. When the magnetic layer contains Nb₂O₅, the magnetic separation of the magnetic particles can be improved.

The content of Nb₂O₅ in the magnetic layer is more preferably 20 mol % or less. If the content of Nb₂O₅ is more than 20 mol %, the crystallinity of the magnetic grains may be impaired. On the other hand, in order to improve effectively the magnetic separability, the content of Nb₂O₅ in the magnetic layer is preferably 2 mol % or more.

If necessary, the magnetic layer further contains Cr, Ru, Pt, Fe, Cu, W, Mn, Zr, B and/or Mo as metal components, and it may further contain TiO₂, SiO₂, B₂O₃, Cr₂O₃ and/or CoO as metal oxide components.

### (Method for Producing Laminated Film)

Each layer in the laminated film can be produced by forming each film with a magnetron sputtering apparatus or the like using a sputtering target having a composition and a structure corresponding to each layer thereof.

Here, the intermediate layer in the laminated film is formed on the base layer by sputtering using the above sputtering target.

The magnetic layer in the laminated film is preferably formed on the intermediate layer by sputtering using the sputtering target containing Co and Pt as the metal components, which has a composition corresponding to the composition of the magnetic layer.

### (Magnetic Recording Medium)

The magnetic recording medium is provided with the laminated film including the base layer, the intermediate layer formed on the base layer, and the magnetic layer formed on the intermediate layer as described above. The magnetic recording medium is usually produced by sequentially forming a soft magnetic layer, a base layer, an intermediate layer, a magnetic layer, a protective layer, and the like on a substrate made of aluminum, glass or the like.

### Examples

Next, the sputtering target according to present invention was experimentally conducted and effects exerted by an intermediate layer formed by the sputtering target were confirmed as described below. However, the description herein is merely for the purpose of illustration and is not intended to be limited thereto.

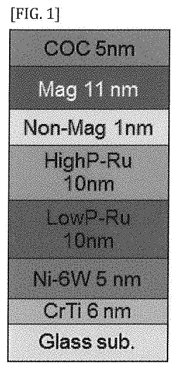

Using various sputtering targets, each laminated film having the layer structure shown in FIG. 1 was produced.

Here, the magnetic layers shown as “Mag” in FIG. 1 were of three types having different compositions: (Co-25Pt)-5TiO₂-3.5SiO₂-1.5Nb₂O₅; (Co-25Pt)-7TiO₂-5SiO₂; and (Co-25Pt)-4.5TiO₂-3SiO₂, and for each of these magnetic layers, intermediate layers indicated as “Non-Mag” on the lower side were changed as shown in Table 1 to produce a plurality of laminated films. Saturation magnetization Ms, magnetic anisotropy Ku, and a slope a in a coercive force of a magnetization curve of each magnetic layer in each laminated film were measured, respectively.

Here, the saturation magnetization Ms and the slope a of the magnetization curve were measured with a vibrated sample type magnetometer (VSM) available from TAMAGAWA CO., LTD., and the magnetic anisotropy Ku was measured by a magnetic torque meter (TRQ) available from TAMAGAWA CO., LTD. A volume fraction of the oxide was determined by calculating a volume of the entire target and a volume of the oxide based on the density and weight of the raw material powder, and obtaining a ratio of them.

In Table 1, “x” in the “Effect” section means that there was no reduction effect of α, “◯” means that there was a reduction effect of α, and “⊚” means that there was a remarkable reduction effect of α, respectively.

TABLE 1

| | | | | | Mag Layer | (Co—25Pt)—5TiO2—3.5SiO2—1.5Nb2O5 | | | |
|---|---|---|---|---|---|---|---|---|---|
| | | | | | Composition → | Oxide Volume Fraction: | | | |
| | Nonmagnetic Oxide layer, | | | | Oxide Volume | 29.9 vol % | | | |
| | Composition (mol %) | | | | Fraction | Ms | Ku | α | Effect |
| Inventive Example 1 | (Co—20Cr—20Ru)—3Nb2O5 | | | | 20.0 | 737 | 7.6 | 3.7 | ◯ |
| Inventive Example 2 | (Co—20Cr—20Ru)—4Nb2O5 | | | | 25.5 | 734 | 7.5 | 3.7 | ◯ |
| Inventive Example 3 | (Co—20Cr—20Ru)—5Nb2O5 | | | | 30.0 | 733 | 7.7 | 2.9 | ⊚ |
| Inventive Example 4 | (Co—20Cr—20Ru)—6Nb2O5 | | | | 34.3 | 735 | 7.6 | 2.3 | ⊚ |
| Inventive Example 5 | (Co—20Cr—20Ru)—7Nb2O5 | | | | 38.0 | 734 | 7.5 | 1.8 | ⊚ |
| Inventive Example 6 | (Co—20Cr—20Ru)—1.5Nb2O5—10TiO2 | | | | 30.3 | 734 | 7.5 | 3.5 | ◯ |
| Inventive Example 7 | (Co—20Cr—20Ru)—2Nb2O5—8.3TiO2 | | | | 30.0 | 735 | 7.4 | 2.9 | ⊚ |
| Inventive Example 8 | (Co—20Cr—20Ru)—4Nb2O5—6.5TiO2 | | | | 35.5 | 736 | 7.5 | 2 | ⊚ |
| Inventive Example 9 | (Co—20Cr—20Ru)—1.5Nb2O5—14.5CoO | | | | 30.0 | 730 | 7.5 | 3.7 | ◯ |
| Inventive Example 10 | (Co—20Cr—20Ru)—2Nb2O5—12.5CoO | | | | 30.2 | 733 | 7.6 | 2.9 | ⊚ |
| Inventive Example 11 | (Co—20Cr—20Ru)—4Nb2O5—9CoO | | | | 35.1 | 735 | 7.4 | 2.1 | ⊚ |
| Inventive Example 12 | (Co—20Cr—20Ru)—1.5Nb2O5—7.5SiO2 | | | | 31.2 | 735 | 7.7 | 3.5 | ◯ |
| Inventive Example 13 | (Co—20Cr—20Ru)—2Nb2O5—6SiO2 | | | | 30.0 | 736 | 7.6 | 3.2 | ◯ |
| Inventive Example 14 | (Co—20Cr—20Ru)—4Nb2O5—5SiO2 | | | | 36.2 | 735 | 7.5 | 2.1 | ⊚ |
| Comparative Example 1 | Non | | | | | 710 | 6.5 | 3.8 | — |
| Comparative Example 2 | (Co—20Cr—20Ru)—8.5TiO2 | | | | 19.8 | 730 | 7.5 | 4 | X |
| Comparative Example 3 | (Co—20Cr—20Ru)—14TiO2 | | | | 30.0 | 726 | 7.6 | 3.7 | ◯ |
| Comparative Example 4 | (Co—20Cr—20Ru)—17TiO2 | | | | 35.0 | 723 | 7.5 | 3.1 | ◯ |
| Comparative Example 5 | (Co—20Cr—20Ru)—12.5SiO2 | | | | 35.5 | 745 | 7.6 | 3.7 | ◯ |
| | | (Co—25Pt)—7TiO2—5SiO2 | | | | (Co—25Pt)—4.5TiO2—3SiO2 | | | |
| | | Oxide Volume Fraction: | | | | Oxide Volume Fraction: | | | |
| | | 29.5 vol % | | | | 19.8 vol % | | | |
| | | Ms | Ku | α | Effect | Ms | Ku | α | Effect |
| | Inventive Example 1 | 702 | 7.2 | 3.8 | ◯ | 762 | 7.6 | 4.7 | ◯ |
| | Inventive Example 2 | 699 | 7.1 | 3.7 | ◯ | 759 | 7.7 | 4.1 | ◯ |
| | Inventive Example 3 | 700 | 7.3 | 2.9 | ⊚ | 757 | 7.8 | 3.7 | ⊚ |
| | Inventive Example 4 | 701 | 7.2 | 2.3 | ⊚ | 758 | 7.7 | 3 | ⊚ |
| | Inventive Example 5 | 699 | 7.1 | 1.8 | ⊚ | 756 | 7.7 | 2.5 | ⊚ |
| | Inventive Example 6 | 698 | 7.2 | 3.6 | ◯ | 757 | 7.6 | 4.3 | ◯ |
| | Inventive Example 7 | 702 | 7 | 2.9 | ⊚ | 758 | 7.7 | 3.6 | ⊚ |
| | Inventive Example 8 | 701 | 7.1 | 2 | ⊚ | 757 | 7.8 | 2.7 | ⊚ |
| | Inventive Example 9 | 700 | 7.1 | 3.7 | ◯ | 757 | 7.7 | 4.4 | ◯ |
| | Inventive Example 10 | 698 | 7.2 | 2.9 | ⊚ | 756 | 7.7 | 3.7 | ⊚ |
| | Inventive Example 11 | 699 | 7.1 | 2.1 | ⊚ | 758 | 7.8 | 2.9 | ⊚ |
| | Inventive Example 12 | 703 | 7.4 | 3.6 | ◯ | 758 | 7.7 | 4.4 | ◯ |
| | Inventive Example 13 | 702 | 7.3 | 3.2 | ◯ | 756 | 7.8 | 3.7 | ⊚ |
| | Inventive Example 14 | 701 | 7.2 | 2.1 | ⊚ | 758 | 7.8 | 2.9 | ⊚ |
| | Comparative Example 1 | 680 | 6.2 | 3.9 | — | 750 | 7.1 | 5.4 | — |
| | Comparative Example 2 | 700 | 7.1 | 4 | X | 760 | 7.8 | 5 | ◯ |
| | Comparative Example 3 | 690 | 7.2 | 3.7 | ◯ | 756 | 7.9 | 4.3 | ◯ |
| | Comparative Example 4 | 688 | 7.1 | 3.1 | ◯ | 752 | 7.8 | 4.1 | ◯ |
| | Comparative Example 5 | 710 | 7.3 | 3.7 | ◯ | 770 | 7.7 | 4.5 | ◯ |

From the results shown in Table 1, it is found that in Inventive Examples 1 to 14 containing Nb₂O₅, the slope α of the magnetization curve is effectively reduced while maintaining the relatively high saturation magnetization Ms and magnetic anisotropy Ku In particular, it is found that when the metal oxide component is only Nb₂O₅, the slope a of the magnetization curve is remarkably reduced if the content of Nb₂O₅ is 5 mol % or more, and when TiO₂ and the like are contained in addition to Nb₂O₅, the slope α of the magnetization curve was significantly reduced if the content of Nb₂O₅ was 2 mol % or more.

However, Comparative Example 1 having no intermediate layer provided lower values of the saturation magnetization Ms and magnetic anisotropy Ku. From the results of Comparative Examples 2 to 4, it is found that when Nb₂O₅ is not contained, the slope α of the magnetization curve tends to be slightly reduced as the content of the metal oxide is increased, but for example in TiO₂ of Comparative Example 4, it causes a decrease in the saturation magnetization Ms. Further, in the SiO₂ of Comparative Example 5, the α is not decreased despite the Ms is increased, so that separation of magnetic particles is insufficient.

In view of the foregoing, it was suggested that according to the present invention, the magnetic separation between the magnetic particles can be improved without greatly decreasing the magnetic anisotropy in the magnetic layer of the magnetic recording medium.

What is claimed is:

1. A sputtering target containing Co and one or more metals including at least Ru of Cr and Ru, as metal components, wherein a molar ratio of a content of the one or more metals including the at least Ru of Cr and Ru to a content of Co is ½ or more, wherein the sputtering target contains Nb₂O₅ as a metal oxide component, wherein the sputtering target has a content of Nb₂O₅ of from 2 mol % to 5 mol % and further comprises at least one metal oxide other than Nb₂O₅, and wherein the sputtering target has a total content of metal oxides including Nb₂O₅ of 30 vol % or more.

2. The sputtering target according to claim 1, wherein the at least one metal oxide other than the Nb₂O₅ is at least one metal oxide selected from the group consisting of TiO₂, SiO₂, B₂O₃, CoO, CO₃O₄, Cr₂O₃, Ta₂O₅, ZnO, and MnO.

3. The sputtering target according to claim 1, wherein the sputtering target contains Co in an amount of from 15 mol % to 60 mol %.

4. The sputtering target according to claim 1, wherein the sputtering target contains Cr and/or Ru, and wherein a total content of Cr and Ru is from 30 mol % to 60 mol %.

5. The sputtering target according to claim 1, wherein the sputtering target further contains Pt in an amount of from 5 mol % to 30 mol % as a metal component.

6. A method for producing a laminated film, comprising forming an intermediate layer on a base layer containing Ru by sputtering using the sputtering target according to claim 1.

7. The method for producing the laminated film according to claim 6, further comprising forming a magnetic layer on the intermediate layer by sputtering using a sputtering target containing Co and Pt as metal components.
